(19) United States
(12) Patent Application Publication
(10) Pub. No.: US 2011/0100291 A1
(43) Pub. Date: May 5, 2011

(54) PLANT AND METHOD FOR LARGE-SCALE AMMONOTHERMAL MANUFACTURING OF GALLIUM NITRIDE BOULES

(75) Inventor: MARK P. D'EVELYN, Goleta, CA (US)

(73) Assignee: SORAA, INC., Goleta, CA (US)

(21) Appl. No.: 12/697,171

(22) Filed: Jan. 29, 2010

Related U.S. Application Data
(60) Provisional application No. 61/148,340, filed on Jan. 29, 2009.

(51) Int. Cl. C30B 11/00; C30B 25/00

(52) U.S. Cl. 117/11; 117/224

(57) ABSTRACT

A method of operating a high pressure system for growth of gallium nitride containing materials. The method comprises providing a high pressure apparatus comprising a growth region and feedstock region. The high pressure reactor comprises a high pressure enclosure and is configured within a primary containment structure. The method includes operating an exhaust system coupled to the primary containment structure. The exhaust system is configured to remove ammonia gas derived from at least 0.3 liters of ammonia liquid.

### CROSS-REFERENCES TO RELATED APPLICATIONS

This application claims priority to U.S. Provisional Application No. 61/148,340, filed Jan. 29, 2009, commonly assigned, and incorporated by reference for all purpose herein.

### BACKGROUND OF THE INVENTION

The present invention generally relates to processing of materials for growth of crystals. More particularly, the present invention provides a facility and method for large-scale manufacturing of gallium-containing nitride crystals and/or boules by an ammonobasic or ammonoacidic technique, but there can be others. Such crystals and materials include, but are not limited to, GaN, AN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

Gallium nitride containing crystalline materials serve as a starting point for manufacture of conventional optoelectronic devices, such as blue light emitting diodes and lasers. Such optoelectronic devices have been commonly manufactured on sapphire or silicon carbide substrates that differ in composition from the deposited nitride layers. In the conventional Metal-Organic Chemical Vapor Deposition (MOCVD) method, deposition of GaN is performed from ammonia and organometallic compounds in the gas phase. Although successful, conventional growth rates achieved make it difficult to provide a bulk layer of GaN material. Additionally, dislocation densities are also high and lead to poorer optoelectronic device performance.

Other techniques have been proposed for obtaining bulk monocrystalline gallium nitride. Such techniques include use of epitaxial deposition employing halides and hydrides in a vapor phase and is called Hydride Vapor Phase Epitaxy (HVPE) [“Growth and characterization of freestanding GaN substrates” K. Motoku et al., Journal of Crystal Growth 237-239, 912 (2002)]. Unfortunately, drawbacks exist with HVPE techniques. In some cases, the quality of the bulk monocrystalline gallium nitride is not generally sufficient for high quality laser diodes because of issues with dislocation density, stress, and the like. In addition, as a one- or few-at-a-time technique, the wafers so produced tend to be expensive and difficult to manufacture.

Techniques using supercritical ammonia have been proposed. Peters has described the ammonothermal synthesis of aluminum nitride [J. Cryst. Growth 104, 411-418 (1990)]. R. Dwilinski et al. have shown, in particular, that it is possible to obtain a fine-crystalline gallium nitride by a synthesis from gallium and ammonia, provided that the latter contains alkali metal amides (KNH₂ or LiNH₂). These and other techniques have been described in “AMMONO method of BN, AlN, and GaN synthesis and crystal growth”, Proc. EGW-3, Warsaw, Jun. 22 24, 1998, MRS Internet Journal of Nitride Semiconductor Research, http://nsr.mij.mrs.org/3/25, “Crystal growth of gallium nitride in supercritical ammonia” J. W. Kolis et al., J. Cryst. Growth 222, 431-434 (2001), and Mat. Res. Soc. Symp. Proc. 495, 367-372 (1998) by J. W. Kolis et al. However, using these supercritical ammonia processes, no wide scale production of bulk monocrystalline gallium nitride was achieved.

Referring to other crystalline materials, quartz crystals, plus a few other oxide crystal compositions, are manufactured on a large scale commercially, and methods for operating hydrothermal processes efficiently and safely are known in the art. However, handling of high pressure ammonia offers a number of additional challenges, and we are unaware of any descriptions of ammonothermal processing facilities that are suitable for large scale manufacturing of gallium nitride boules.

From the above, it is seen that techniques for large scale ammonothermal crystal manufacturing are highly desired.

### BRIEF SUMMARY OF THE INVENTION

According to the present invention, techniques related to processing of materials for crystal growth are provided. More particularly, the present invention provides a facility and method for large-scale manufacturing of gallium-containing nitride crystals and/or boules by an ammonobasic or ammonoacidic technique, but there can be others. Such crystals and materials include, but are not limited to, GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

In a specific embodiment, the present invention provides a high pressure reactor system for growth of gallium nitride containing materials. The system includes a primary containment structure. The system also includes a high pressure apparatus comprising a growth region and feedstock region. The high pressure reactor comprises a high pressure enclosure. In a specific embodiment, the high pressure apparatus is configured within the primary containment structure. The system also has an exhaust system coupled to the primary containment structure. In a preferred embodiment, the exhaust system is configured to remove ammonia gas derived from at least 0.3 liters of ammonia liquid.

In a specific embodiment, the present invention provides a method of operating a high pressure system for growth of gallium nitride containing materials. The method comprises providing a high pressure apparatus comprising a growth region and feedstock region. The high pressure reactor comprises a high pressure enclosure and is configured within a primary containment structure. The method includes operating an exhaust system coupled to the primary containment structure. The exhaust system is configured to remove ammonia gas derived from at least 0.3 liters of ammonia liquid.

Benefits are achieved over pre-existing techniques using the present invention. In particular, the present invention enables a cost-effective and safe system for an high pressure apparatus for growth of crystals such as GaN, AN, InN, InGaN, and AlInGaN and others. In a specific embodiment, the present method and system can operate with components that are relatively simple and cost effective to manufacture. Depending upon the embodiment, the present system and method can be manufactured using conventional materials and/or methods according to one of ordinary skill in the art. The present system and method enable cost-effective crystal growth and materials processing under extreme pressure and temperature conditions in batch volumes larger than 3 liters, larger than 10 liters, larger than 30 liters, larger than 100 liters, and larger than 300 liters according to a specific embodiment. In a preferred embodiment, the system allows for safe containment of a toxic gas, such as ammonia or the like, and contains the gas, which is subjected to high pressure in the apparatus. Depending upon the embodiment, one or more of these benefits may be achieved. These and other benefits may be described throughout the present specification and more particularly below.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1 is a simplified schematic illustration of an embodiment of the present invention;

FIG. 2 is a simplified schematic illustration of another embodiment of the present invention; and

FIG. 3 is a simplified isochore graph for ammonia showing pressure as a function of temperature and percent fill.

### DETAILED DESCRIPTION OF THE INVENTION

According to the present invention, techniques related to processing of materials for crystal growth are provided. More particularly, the present invention provides a facility and method for large-scale manufacturing of gallium-containing nitride crystals and/or boules by an ammonobasic or ammonoacidic technique, but there can be others. Such crystals and materials include, but are not limited to, GaN, AN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

In the discussion that follows, the ammonothermal crystal growth apparatus is described as being vertically oriented. In another embodiment, the apparatus is instead horizontally oriented or oriented at an oblique angle intermediate between vertical and horizontal, and may be rocked so as to facilitate convection of the supercritical fluid within the high pressure apparatus. The present methods may be used in conjunction with a sealable container and high pressure apparatus. Examples of representative applicable apparatus include autoclaves, as are described in U.S. Pat. No. 7,160,388 and Japanese Patent Publication Nos. JP2005289797 and JP2007039321, which are hereby incorporated by reference in their entirety. Additional examples of representative applicable apparatus include internally heated apparatus, as described in U.S. Pat. Nos. 7,101,433, 7,125,453, and in U.S. patent application Ser. Nos. 61/073,687, 61/087,122, 12/334,418, 12/133,365 and 12/133,364, all of which are hereby incorporated by reference in their entirety. One of ordinary skill in the art would recognize other variations, modifications, and alternatives.

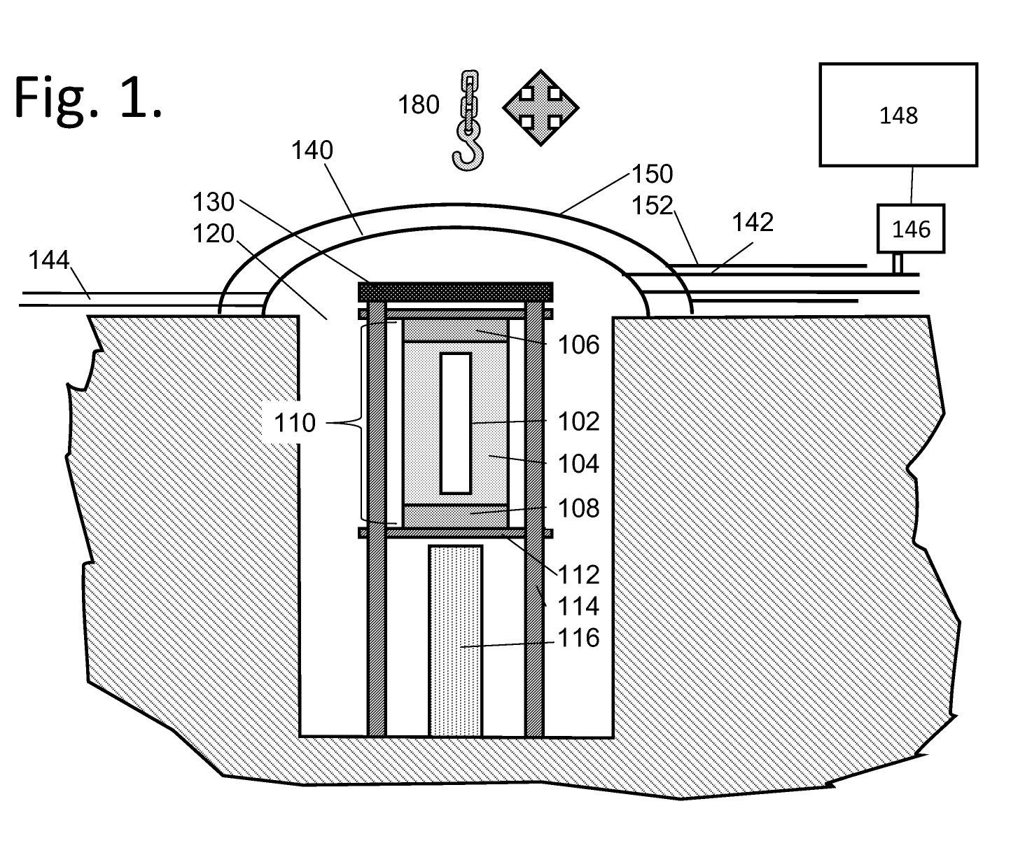

A portion of a plant or facility for large-scale ammonothermal manufacturing of gallium nitride boules is shown schematically in FIG. 1. A high pressure reactor 110 may comprise a cavity or capsule region 102 in which materials such as gallium nitride may be processed in supercritical ammonia. Reactor 110 may comprise an autoclave, with a top closure 106. Reactor 110 may comprise a high strength enclosure 104 and may comprise a top flange or closure 106 and a bottom flange or closure 108. Reactor 110 may be mechanically supported by one or more plates 112, posts 114, and the like. Reactor 110 may be capable of containing liquid or supercritical ammonia batch volumes larger than 0.3 liters, larger than 1 liter, larger than 3 liters, larger than 4.5 liters, larger than 10 liters, larger than 30 liters, larger than 100 liters, or larger than 300 liters according to a specific embodiment. Reactor 110 may have an outer diameter between 4 inches and about 100 inches, or between about 12 inches and about 48 inches. Reactor 110 may have a height between about 6 inches and about 500 inches, or between about 24 inches and about 120 inches. A hydraulic cylinder 116 may also be provided, to assist with movement of flanges, capsules, or other components of the high pressure reactor.

Reactor 110 and the ancillary assembly may be placed in a pit 120. Pit 120 may be lined with steel-reinforced concrete. The thickness of the concrete with respect to the surface of the pit may be at least 2 inches, at least 4 inches, at least 8 inches, at least 12 inches, at least 18 inches, or at least 24 inches. The concrete thickness may be chosen such that a high-velocity fragment, produced in the unlikely event of a catastrophic failure and fracture of the high pressure reactor, may be partially penetrated but not perforated by the fragment. The concrete may be surrounded by a steel jacket. The pit may be substantially free of openings or cracks that penetrate entirely through the thickness so as to be air tight. The pit may be lined with a liner or coating. The liner or coating may be airtight. The liner may comprise at least one of stainless steel, steel, iron alloy, nickel alloy, cobalt alloy, copper alloy, polyurethane, vinyl, polyvinyl chloride, epoxy-based paint, silicone-based sealant, ceramic tile, grout, porcelain, or the like. The pit may have a drain at the lower level to allow fluids resulting from spills to be easily removed. The pit may have a sump pump to allow for removal of fluids or spills. As additional protection against high velocity fragments, one or more segments of armor plate 130 may be placed proximal to reactor 110. The armor plate may comprise steel, an iron alloy, a nickel alloy, a cobalt alloy, a ceramic, concrete, Kevlar (a trademark of the DuPont Corporation), ceramic or carbon fiber, a composite, or a multilayer structure. The pit may be covered by a removable first cover 140. First cover 140, together with pit 120, may constitute a primary containment structure for high pressure reactor 110. First cover 140 may make an airtight seal with respect to the pit, so that ammonia released by leaks or a sudden rupture is not released into the room, possibly endangering operators. First cover 140 may be fitted with an outlet tube 142 and an inlet tube 144. A purge gas such as nitrogen or argon may be fed into the inlet tube 144 and exhausted through the outlet tube 142 during operation of the high pressure reactor. The outlet tube 142 may be fitted with an ammonia sensor 146 for detection of leaks in the high pressure apparatus, allowing for shutdown of the electrical power to the high pressure reactor by means of an electrical signal to electrical control system 148 before a possibly dangerous condition develops. Ammonia sensor 146 may be coupled to an alarm system, so as to alert operators in case of a leak. An exhaust system may comprise outlet tube 142 and ammonia sensor 146. Outlet tube 142 may be interfaced to an ammonia scrubber system and/or to an air dilution system (not shown). The exhaust system may be configured to remove substantially all the ammonia gas derived from at least 0.3 liters, at least 1 liter, at least 3 liters, at least 4.5 liters, at least 10 liters, at least 30 liters, at least 100 liters, or at least 300 liters of ammonia liquid, according to a specific embodiment. Pit 120 may also be provided with a second cover 150, as additional protection in case of an ammonia leak. Second cover 150 may be provided with an exhaust outlet 152. Exhaust outlet 152 may be coupled to an exhaust fan, which provides a continuous or intermittent flow of purging air so that any ammonia that leaks will be entrained in the purge air and removed before it can harm an operator.

The reactor station may also be equipped with a hoist 180 or other suitable access device. Hoist 180 may be suspended from a track proximate to the ceiling of the building or facility, and may be translatable horizontally as well as vertically. Hoist 180 may be capable of lifting one or more of the components within or above the pit, including reactor 110. Hoist 180 may be translated horizontally to service reactors in two or more pits located proximally to one another. In one specific embodiment, at least four pits with reactors are positioned in a row and may be serviced by a common hoist. In other embodiments, at least six, eight, ten, fifteen, or twenty pits with reactors are positioned in a row or in close proximity and may be serviced by a common hoist. Of course, there can be other variations, modifications, and alternatives.

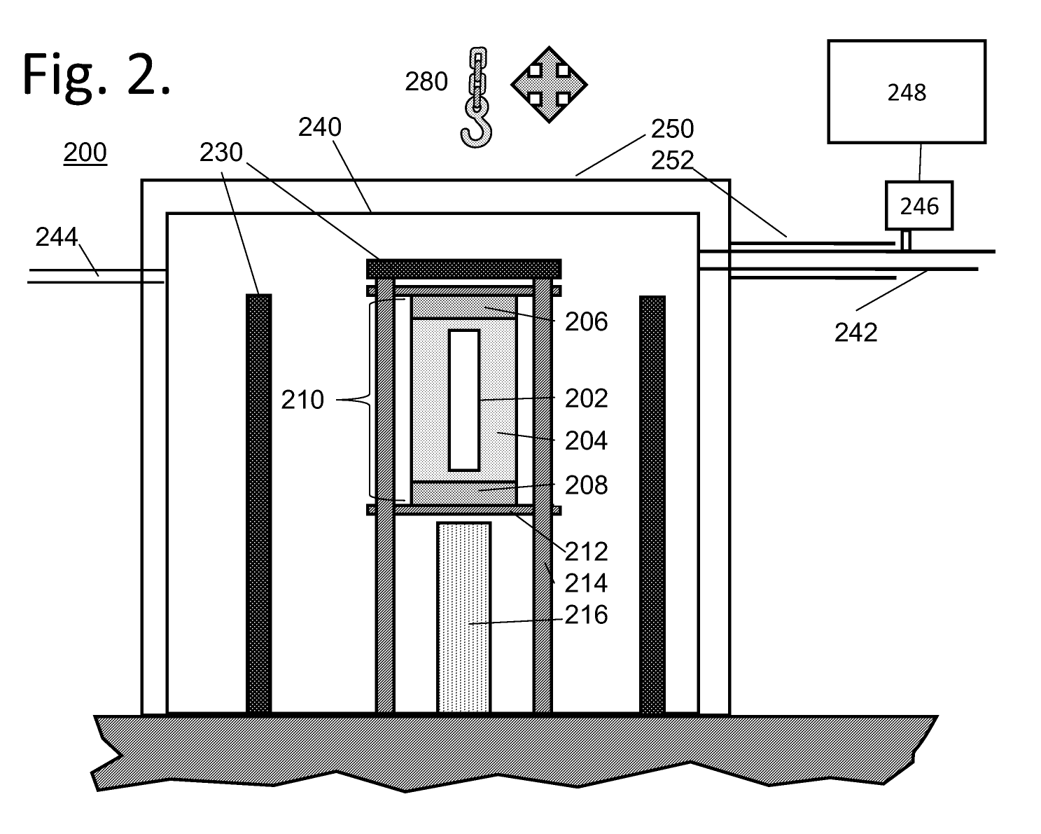

In another embodiment, a single reactor station 200 in a plant or facility for large-scale ammonothermal manufacturing of gallium nitride boules is shown schematically in FIG. 2. A high pressure reactor 210 may comprise a cavity or capsule region 202 in which materials such as gallium nitride may be processed in supercritical ammonia. Reactor 210 may also comprise a high strength enclosure 204 and may comprise a top flange or closure 206 and a bottom flange or closure 208. Reactor 210 may be mechanically supported by one or more plates 212, posts 214, and the like. At least one post 214 may be bolted to the floor. Reactor 210 may be capable of containing liquid or supercritical ammonia batch volumes larger than 0.3 liters, larger than 1 liter, larger than 3 liters, larger than 10 liters, larger than 30 liters, larger than 100 liters, or larger than 300 liters according to a specific embodiment. Reactor 210 may have an outer diameter between 4 inches and about 100 inches, or between about 12 inches and about 48 inches. Reactor 210 may have a height between about 6 inches and about 500 inches, or between about 24 inches and about 120 inches. A hydraulic cylinder 216 may also be provided, to assist with movement of flanges, capsules, or other components of the high pressure reactor.

Reactor 210 and the ancillary assembly may be enclosed within protective shell 240. Protective shell 240 may comprise stainless steel, steel, an iron-based alloy, aluminum, an aluminum-based alloy, nickel, a nickel-base alloy, polycarbonate, polyurethane, vinyl, polyvinyl chloride, Kevlar (a trademark of the DuPont Corporation), carbon fiber, ceramic fiber, a composite, a multilayer structure, or the like. Protective shell 240 may have a thickness between about 0.05 inch and about 6 inches, or between about 0.12 inch and about 2 inches. Protective shell 240 may be airtight or may allow for some gas leakage. Protective shell 240 may comprise a door, for access, may comprise a hinge for opening as a clamshell-type structure, and may comprise at least one fastener for anchoring two or more components together, such as end panels. Protective shell 240, together with the floor, to which reactor 210 may be anchored, may serve as a primary containment structure. As additional protection against high velocity fragments, one or more segments of armor plate 230 may be placed proximal to reactor 210. The armor plate may comprise steel, an iron alloy, a nickel alloy, a cobalt alloy, a ceramic, concrete, ceramic or carbon fiber, a composite, or a multilayer structure. Protective shell 240 may be fitted with an outlet tube 242 and an inlet tube 244. A purge gas such as nitrogen or argon may be fed into the inlet tube 244 and exhausted through the outlet tube 242 during operation of the high pressure reactor. Protective shell 240 may be kept at a pressure below ambient during operation of reactor 210, so that an ammonia leak does not escape from protective shell 240, possibly endangering an operator. The outlet tube 242 may be fitted with an ammonia sensor 246 for detection of leaks in the high pressure apparatus, allowing for shutdown of the electrical power to the high pressure reactor by means of an electrical signal to electrical control system 248 before a possibly dangerous condition develops. Outlet tube 242 may be interfaced to an ammonia scrubber system and/or to an air dilution system (not shown).

Ammonia sensor 246 may be coupled to an alarm system, so as to alert operators in case of a leak. An exhaust system may comprise outlet tube 242 and ammonia sensor 246. The exhaust system may be configured to remove substantially all the ammonia gas derived from at least 0.3 liters, at least 1 liter, at least 3 liters, at least 4.5 liters, at least 10 liters, at least 30 liters, at least 100 liters, or at least 300 liters of ammonia liquid according to a specific embodiment. Reactor station 200 may also be provided with a secondary shell 250, as additional protection in case of an ammonia leak. Secondary shell 250 may be provided with an exhaust outlet 252. Exhaust outlet 252 may be coupled to an exhaust fan, which provides a continuous or intermittent flow of purging air so that any ammonia that leaks will be entrained in the purge air and removed before it can harm an operator. In a specific embodiment, the exhaust is configured to remove any toxic gases such as ammonia, to a level that is safe for operator exposure, within a predetermined time of 24 hours, a few hours, 1 hour, or within minutes, depending upon the embodiment. Of course, there can be other variations, modifications, and alternatives.

Reactor station 200 may also be equipped with a hoist 280. Hoist 280 may be suspended from a track proximate to the ceiling of the building or facility or of protective shell 240, and may be translatable horizontally as well as vertically. Hoist 280 may be capable of lifting one or more of the reactor station components, including reactor 210. Hoist 280 may be translated horizontally to service two or more reactor stations. In one specific embodiment, at least four reactor stations are positioned in a row and may be serviced by a common hoist. In other embodiments, at least six, eight, ten, fifteen, or twenty reactor stations are positioned in a row or in close proximity and may be serviced by a common hoist.

The process requirements for large scale ammonothermal processing or crystal growth may be estimated from the equation of state for ammonia [Reference: URL http://webbook.nist.gov/chemistry/fluid/]. The data tabulated by the National Institute for Standards and Technology may not extend to as high a temperature and pressure as the desired condition but may be estimated by means of a polynomial fit of the tabulated NIST data followed by extrapolation. The tabulated data assumes no dissociation of ammonia. However, under ammonothermal processing conditions, some dissociation of ammonia into nitrogen and hydrogen may occur:

1/2N₂+3/2H₂=NH₃

The equilibrium constant K_{eq} for the ammonia formation reaction (the reverse reaction of that for dissociation) may be calculated from the free energy of formation, ΔG₀, calculated from tabulated thermodynamic data, for example, I. Barin, Thermochemical Data of Pure Substances, 3^{rd} edition (VCH, Weinheim, 1993). Assuming that equilibrium is reached, the partial pressures of ammonia, hydrogen, and nitrogen may be estimated by assuming that the partial pressures p_{α} of each component α are approximately equal to their fugacities f_{α} and are equal to their respective mole fractions times the initial pressure of undissociated ammonia:

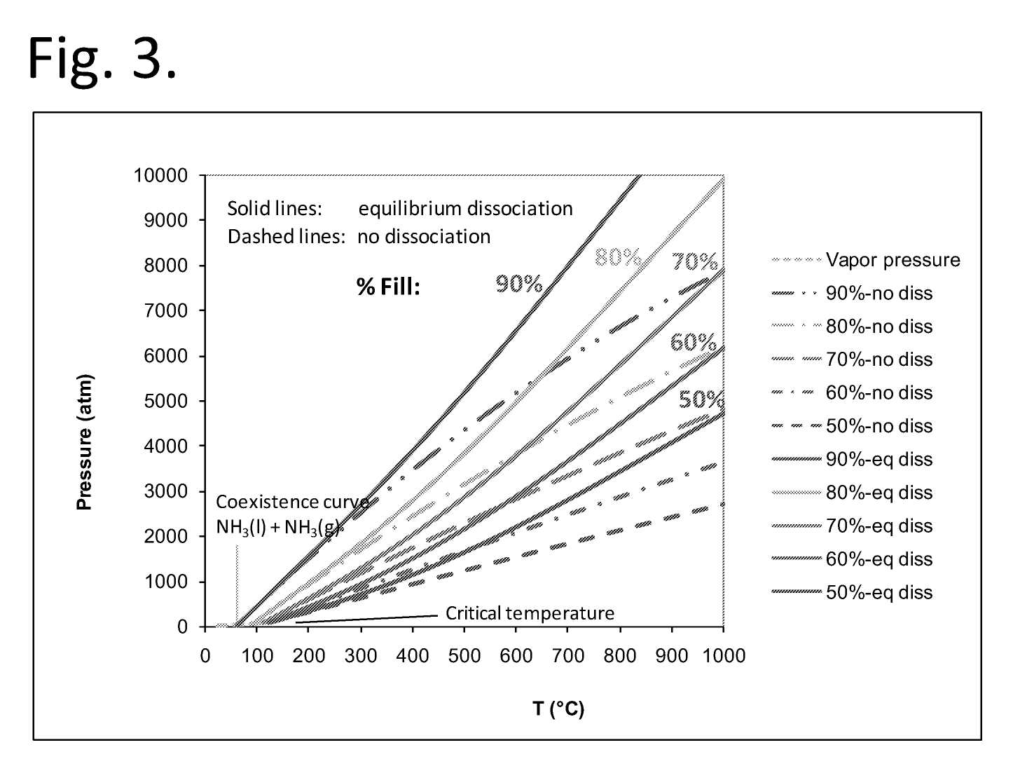

K_{eq}=exp[−ΔG₀/RT]=f_{NH}_{₂}^{1/2}f_{H}_{₂}^{3/2})≈p_{NH}_{₃}/(p_{N}₂^{1/2}p_{H}_{₂}^{3/2})

where R is the gas constant and T is the temperature in Kelvin. Making these approximations, the total pressure as a function of temperature for various percent fills is shown in FIG. 3. These assumptions are known to overestimate the extent of ammonia decomposition and therefore the pressure. The estimated pressure, as a function of temperature and percent fill of ammonia, is shown in FIG. 3. The percent fill is calculated as the weight of initially-added ammonia divided by the available volume within the high pressure apparatus, divided by the density of liquid ammonia at room temperature, 0.6 grams per cubic centimeter, and expressed as a percentage.

As a first example, a high pressure reactor has an internal working diameter of 3.5 inches and an internal height of 30 inches, corresponding to an internal volume of approximately 4.7 liters. Approximately 80% of the free internal volume is filled with liquid ammonia, the reactor is sealed, and then the reactor is heated. The reactor is operated at 500 degree Celsius. Referring to FIG. 3, the pressure is estimated as about 3829 atmospheres. This is a conservative estimate (viz., an overestimate), since the ideal gas assumptions described above are known to overestimate the extent of ammonia decomposition. The high pressure apparatus, for example, an autoclave or an internally heated pressure apparatus, should be capable of supporting the process pressure at the chosen process temperature and percent fill for a period of many months at an engineering safety factor that is consistent with local laws and safety considerations.

The high pressure reactors are designed so that leaks and other types of failure do not occur during normal operation. However, in view of the hazards associated with various types of potential failures, enclosures, ventilation, and other types of safety protection may be provided to provide a safe environment for operators and other personnel at the ammonothermal processing facility even in the unlikely event of a failure. The most severe type of failure is a sudden rupture or leak of the reactor, producing a sudden release of ammonia and, potentially, high velocity fragments associated with fracture of a portion of the reactor.

In order to properly assess and quantify the appropriate level of containment, the stored energy in the reactor under operating conditions, typically referred to as the blast energy, may be calculated. Typically, the stored energy in the supercritical ammonia greatly exceeds the stored mechanical energy in the reactor, and therefore the latter may be safely neglected. Many of the formulas and estimates described below are drawn from the ME Design Safety Standards Manual, Chapter 4.1, “Personnel and Equipment Shields,” Revision Date September 1994, Lawrence Livermore National Laboratory, which is hereby incorporated by reference in its entirety.

The blast energy E_{blast} associated with a sudden release of the ammonia may be estimated, conservatively, from the equation

E_{blast}=(P₀−P_{amb})V₀/(γ−1),

where P₀ is the operating pressure, P_{amb} is ambient pressure, V₀ is the internal volume of the reactor, and γ=C_{P}/C_{V} is the heat capacity ratio of the working ammonia fluid. The equation is conservative because it assumes the fluid is an ideal gas and neglects the condensation that ammonia will undergo upon a sudden release, which may in fact produce a nearly isentropic (adiabatic) expansion. Under the chosen operating conditions the heat capacity ratio of the ammonia is approximately 1.3 and, substituting in the values listed above, the blast energy is estimated conservatively as about 60,300 liter-atmospheres or about 6100 kJ, corresponding to an equivalent of about 1.3 kg of TNT (trinitrotoluene).

The peak overpressure that develops within the pit or primary container that houses the reactor may be estimated from:

Pₚₒᵥ[kPa]6×2225(E_{blast}/Vᵥ)^{0.72}

where E_{blast} is given in units of the equivalent weight of TNT in kilograms and Vᵥ is the volume of the pit or primary container in units of cubic meters. With the reactor placed in a pit that has an inner diameter of 5 feet and a depth of 10 feet, the volume is approximately 5.6 cubic meters. The blast energy of about 1.3 kg equivalent of TNT gives rise to a peak overpressure in the pit of approximately 20.6 atmospheres. The walls of the pit, the primary cover for the pit, and the fasteners holding the assembly together should be capable of withstanding a pressure of this magnitude for at least a brief duration. The exhaust system should be configured to remove the ammonia, and possibly other toxic gases, without exposing any operators to an unsafe condition. The decay time of the pressure burst accompanying a sudden release will be determined by the ratio of the volume of the primary containment system to the conductance of the exhaust system. Rapid decay of an overpressure may be achieved by configuring the exhaust system to have a large conductance, for example, by providing a large-diameter outlet tube. Removal of residual ammonia, and possibly other toxic gases, may be facilitated by providing a constant purge of an inert gas such as nitrogen or argon, through an inlet tube.

In the unlikely event of fracture of the high pressure reactor during a catastrophic leak, one or more fragments may be generated. The velocity of the fragments may be estimated, conservatively, by assuming that half the overall blast energy is converted into the kinetic energy of the fragment. For maximum safety, shielding or armor may be present to contain the fragments and avoid exposing operators of the reactor to the risk of high-velocity shrapnel.

The high pressure reactor may have a large-diameter bolt whose shear may be the most likely scenario for producing a high-velocity fragment in the unlikely event of a catastrophic failure. The end of the bolt may weigh approximately 0.9 kilogram and have an outward-facing cross sectional area of approximately 0.0022 square meters. Assuming that 50% of the blast energy is converted to kinetic energy of the bolt fragment, the velocity of the bolt fragment may be estimated as about 2600 meters per second. Using various formulas for predicting penetration of projectiles into armor, the thickness of steel required to safely contain this fragment may be estimated to lie between about 2 inches and about 10 inches.

In a second example, the same high pressure reactor is operated with a liquid ammonia fill of 80% but the temperature is raised to 800 degrees Celsius. Referring to FIG. 3, the pressure is estimated conservatively as 7411 atmospheres. Using the same equations as described above, the blast energy is estimated conservatively as about 14,200 kJ, corresponding to an equivalent of about 3.1 kg of TNT. In the same pit, the peak overpressure that may develop during the blast may be estimated as approximately 90 atmospheres. Assuming that 50% of the blast energy is converted to kinetic energy of the bolt fragment, the velocity of the bolt fragment may be estimated as about 4000 meters per second. Using various formulas for predicting penetration of projectiles into armor, the thickness of steel required to safely contain this fragment may be estimated to lie between about 2 inches and about 16 inches.

The manufacturing facility may also be equipped with a number of additional facilities for preparing cells for bulk crystal growth, filling them with ammonia, sealing, removing the cells from the high pressure reactor, removing the ammonia from the cells, recycling the ammonia, removing gallium nitride boules from the cells, and preparing gallium nitride wafers from the gallium nitride boules.

A glove box may be provided for handling raw materials, loading raw materials into capsules, and welding capsules. A welding facility may be provided for welding capsules. The welding facility may comprise an arc welding power supply and torch. An ammonia source may be provided. The ammonia source may comprise a gaseous ammonia source or a liquid ammonia source. In a preferred embodiment, the ammonia source is capable of providing ammonia to the capsule, autoclave, or high pressure reactor at a pressure of at least about 7 atmospheres. A sealing facility may also be provided. A sealing facility may comprise an ultrasonic tube sealer for sealing of fill tubes on the capsules. A facility may also be provided for capturing and recycling ammonia, such as that described in U.S. patent application Ser. No. 61/087,122, filed on Aug. 7, 2008, commonly assigned, and which is hereby incorporated by reference in its entirety.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A high pressure reactor system for growth of gallium nitride containing materials, the system comprising:
a primary containment structure;
a high pressure apparatus comprising a growth region and feedstock region, the high pressure reactor comprising a high strength enclosure, the high pressure apparatus configured within the primary containment structure;
an exhaust system coupled to the primary containment structure, the exhaust system being configured to remove ammonia gas derived from at least 0.3 liters of ammonia liquid.

2. The system of claim 1 further comprising an inlet coupled to the high pressure apparatus.

3. The system of claim 1 wherein the high pressure apparatus is an autoclave.

4. The system of claim 1 wherein the high pressure apparatus is an internally-heated high pressure apparatus.

5. The system of claim 1 wherein the primary containment structure is substantially sealed from an exterior region.

6. The system of claim 1 further comprising one or more sensors configured within one or more spatial regions of the primary containment structure, the one or more sensors being coupled to an alarm system.

7. The system of claim 1 wherein the one or more sensors are coupled to an electrical control system.

8. The system of claim 1 further comprising a secondary containment structure substantially enclosing the primary containment structure.

9. The system of claim 1 wherein the primary containment structure is configured within an earth structure, the earth structure comprising dirt provided on a portion of the ground.

10. The system of claim 1 wherein the primary containment structure comprises a metal material.

11. The system of claim 1 wherein the primary containment structure comprises a concrete material.

12. The system of claim 1 wherein the exhaust system is configured to remove substantially all of the ammonia gas derived from at least 4.5 liters of ammonia liquid.

13. The system of claim 1 wherein the high pressure apparatus is vertically oriented with respect to gravity.

14. The system of claim 1 wherein the high pressure apparatus is horizontally oriented.

15. The system of claim 1 wherein the high pressure apparatus is at an oblique angle between a horizontal and a vertical orientation.

16. The system of claim 1 wherein the high pressure apparatus comprises an internal heating element.

17. The system of claim 1 wherein the high pressure apparatus comprises an external heating apparatus.

18. The system of claim 1 wherein the high pressure apparatus is configured to hold a volume of ammonia liquid.

19. The system of claim 18 wherein the volume is larger than about 0.3 liters, larger than about 1 liter, larger than about 3 liters, larger than about 10 liters, larger than about 30 liters, larger than about 100 liters, or larger than about 300 liters.

20. The system of claim 1 wherein the primary containment structure is configured substantially or partially within a spatial region within a portion of an earth structure.

21. The system of claim 20 wherein the earth structure comprises a pit.

22. The system of claim 1 wherein the primary containment structure comprises steel-reinforced concrete.

23. The system of claim 22 wherein the steel-reinforced concrete comprises a concrete thickness of at least 2 inches, at least 4 inches, at least 8 inches, at least 12 inches, at least 18 inches, or at least 24 inches.

24. The system of claim 22 wherein the steel-reinforced concrete comprises a steel jacket surrounding the concrete.

25. The system of claim 1 wherein the primary containment structure comprises a liner, the liner being made of a material selected from at least stainless steel, steel, iron alloy, nickel alloy, cobalt alloy, copper alloy, polyurethane, Kevlar, vinyl, polyvinyl chloride, epoxy-based paint, silicone-based sealant, ceramic tile, grout, or porcelain.

26. The system of claim 1 further comprising a drain region coupled to the primary containment structure.

27. The system of claim 1 further comprising a pump coupled to the drain region.

28. The system of claim 1 further comprising a purge line coupled to the primary containment structure.

29. The system of claim 1 further comprising a hoist operably coupled to the high pressure apparatus.

30. The system of claim 1 wherein the high pressure apparatus is substantially coupled to one or more portions of the containment structure.

31. The system of claim 1 further comprising a protective shell configured to enclose the high pressure apparatus, the protective shell being made of a material selected from at least stainless steel, steel, an iron-based alloy, aluminum, an aluminum-based alloy, nickel, a nickel-base alloy, Kevlar, polycarbonate, polyurethane, vinyl, polyvinyl chloride, carbon fiber, ceramic fiber, a composite, or a multilayer structure.

32. The system of claim 1 further comprising one or more armor plates placed within a vicinity of an outer region of the high pressure apparatus.

33. The system of claim 1 wherein the exhaust system is configured to remove ammonia gas to a level that is safe for operator exposure within a period less than twenty-four hours.

34. The system of claim 1 wherein the high pressure apparatus is one of at least four high pressure apparatuses.

35. The system of claim 1 wherein the high pressure apparatus is one of at least ten high pressure apparatuses.

36. A method of operating a high pressure system for growth of gallium nitride containing materials, the method comprising:
providing a high pressure apparatus comprising a growth region and feedstock region, the high pressure reactor comprising:
a high pressure enclosure, the high pressure apparatus configured within a primary containment structure; and
operating an exhaust system coupled to the primary containment structure, the exhaust system being configured to remove ammonia gas derived from at least 0.3 liters of ammonia liquid.
